(19) United States
(12) Patent Application Publication
(10) Pub. No.: US 2026/0017430 A1
(43) Pub. Date: Jan. 15, 2026

(54) INTERACTIVE TRADE SHOW PRESENTATION SYSTEM AND METHOD

(71) Applicant: Kokomo Solutions, Inc., Northbrook, IL (US)

(72) Inventor: Daniel Jongdae Lee, Northbrook, IL (US)

(21) Appl. No.: 19/266,258

(22) Filed: Jul. 11, 2025

Related U.S. Application Data
(60) Provisional application No. 63/670,533, filed on Jul. 12, 2024.

(51) Int. Cl. G06F 30/20

(52) U.S. Cl. CPC G06F 30/20

(57) ABSTRACT

A digital system and associated method for providing an interactive presentation at a trade show, an exhibition, or a school or workplace event. The digital system includes: a platform having memory and at least one processor; a flexible software architecture configured to interact with a user, a plurality of information management modules, and a communication suite; and a user interface. The memory of the platform stores instructions received directly from the user and data relative to the information modules. The stored data is provided to the user through the communication suite upon the at least one processor executing the stored instructions. The digital system simulates the function or operation of a cloud-based system configured to manage school or workplace safety, health, and well-being, thereby, providing the interactive presentation.

### CROSS REFERENCE TO RELATED APPLICATIONS

This application claims the benefit of the filing date under 35 U.S.C. § 119(e) of U.S. Provisional Application No. 63/670,533 filed on Jul. 12, 2024, the entire contents of which is incorporated herein by reference.

### FIELD

The present invention relates to an interactive digital presentation system and method of forming said interactive presentation. More specifically, the disclosure relates to an interactive digital presentation system used at trade shows and the like.

### BACKGROUND

The statements in this section merely provide background information related to the present disclosure, as well as definitions of terms used in the present disclosure and may not constitute prior art.

Trade shows, also known as expositions or exhibitions, have long been pivotal environments for businesses to showcase their products and services, connect with potential customers, and network with industry peers. The concept of a trade show may be traced back to ancient times when merchants and artisans would gather at local marketplaces to sell their goods. These early gatherings were more than just commercial events, rather they represented social and cultural centers where people exchanged not only goods, but also ideas and information. Early trade show “exhibits” utilized a combination of natural resources, such as stone, painted skins, hand-hewn scrap timber, and handmade/homemade paper signage. At that time, trade show exhibit design was the result of a primitive sales and marketing necessity.

During the medieval period, trade fairs became more organized and were often sponsored by local guilds or royalty. These fairs, which were held in towns across Europe, became significant events in the annual calendar, attracting traders from far and wide with slightly more complex stands/stalls. These trade fairs were instrumental in the development of international trade routes and the global spread of new products and innovations.

The Industrial Revolution (beginning ˜1760) marked a pivotal point in the evolution of trade shows. As industries expanded and new technologies emerged, there was a growing need for a place where businesses could showcase their latest inventions and products. The Great Exhibition of 1851 in London, housed in the magnificent Crystal Palace, was a landmark exposition event. The event not only displayed the technological advancements of the era, but also set a precedent for future international exhibitions and exhibit designs.

In the 20th century, trade shows evolved into more specialized events, focusing on specific industries or market sectors. During this period, dedicated exhibition centers around the world were beginning to become established along with professional trade show management. Events like the Consumer Electronics Show (CES) and the Hannover Messe became annual fixtures, drawing global attendance. The “trade show booth” became a true, multidimensional sales and marketing tool. Customized exhibit design along with booth staffing and management became common place.

Continuing throughout the next two centuries, trade shows have played a crucial role in driving the global economy. They provide a platform for businesses to enter new markets, forge international partnerships, and stay abreast of industry trends and competition. Many industries and area residents benefit from trade shows on a global scale. A substantial number of people either exhibit or attend trade shows, in-person each year, which helps small businesses (such as restaurants and cafes) located near the venue grow stronger.

The advent of the internet and digital technologies has further transformed trade shows. Virtual trade shows and hybrid events, combining physical and digital elements, have become increasingly popular, especially in the wake of the global pandemic. Digital platforms have made trade shows more accessible, allowing for broader participation and engagement. While in-person events will likely remain the standard, for the foreseeable future, digital variations and elements have found their niche and at the very least add value to existing, more traditional trade show/event marketing programs.

As we continue to move forward in time, it has become clear that trade shows will continue to evolve. Sustainability and environmental concerns are starting to drive changes in how trade shows are organized and produced, with a focus on reducing carbon footprints and promoting eco-friendly practices. The further advancement of technology will also play a significant role, with XR or Extended Reality (Augmented, Virtual and Mixed reality) offering new ways to experience and interact at these events. Generative AI (Artificial Intelligence) tools, applied to the event industry, are being developed at a lightning pace and will most likely become a critical component of trade shows over the next several decades. There continues to be a need for even further improvement relative to providing multiple functions associated with each individual trade show booth and/or presentation.

In addition, school districts and workplaces usually don't have one centralized dashboard to track and monitor students/employees and/or the occurrence of school or workplace incidents. School districts or employers also don't provide students, staff, or employees with a mobile, text-based, system to report dangerous behavior that occurs. They are not equipping staff/employees or students with a two-way communication enabled panic button in times of severe crisis including the presence of an armed assailant. School districts and workplaces often lack the technical resources to securely manage immunization requirements or provide students and/or employees with proper health resources.

Even in today's climate of violence, school districts and workplaces may not provide adequate means to control or manage the movement of their visitors or guest. School districts and workplaces often lack efficient ways to automate messaging tasks or provide mass communications to all students or employees. They may become more efficient with facility management if they could integrate with a central data repository to visualize all of the data points simultaneously. School districts and workplaces often lack accountability for existing hardware assets and even less accountability for software licenses, leading to an inefficiency in necessary funding. They often don't implement software management tools when holding events in order to effectively manage the health and safety of event attendees. Finally, school districts and workplaces lack accountability for asset patrolling and tracking on their premises, including bus yards, parking lots, and shuttle services.

Until the invention of the present disclosure, these and other problems in the conventional design and operation of trade show presentations went either unnoticed or unsolved by those skilled in the art.

### SUMMARY

The present disclosure provides a system and method that performs multiple functions with associated electronic devices without sacrificing reliability, accessibility, effectiveness, safety or value. Furthermore, by combining multiple functions into a single system, transportability is improved and not diminished. Peripheral devices such as a writing stylus, external speakers, volume and music play controls can all be externalized to the system.

An objective of the present disclosure is to make available a digital system for providing an interactive presentation at a trade show, an exhibition, or a school or workplace event is provided. This digital system generally comprises: a platform having memory and at least one processor; a flexible software architecture configured to interact with a user, a plurality of information management modules, and a communication suite; and a user interface. The memory of the platform stores instructions received directly from the user and data relative to the information modules. The stored data is provided to the user through the communication suite upon the at least one processor executing the stored instructions. The digital system simulates the function or operation of a cloud-based system configured to manage school or workplace safety, health, and well-being. Thus, the trade show, the exhibition, and/or the school or workplace event is relative to safety, health, and well-being.

The communication suite comprises at least one display device configured for use in a building or a confined space and/or at least one mobile device. The at least one display device may include a television screen or a computer screen or monitor. The at least one mobile device may include a cell phone, a personal digital assistant (PDA), or a tablet personal computer. When desirable, the display device and/or mobile device may also be used to display the user interface.

The platform and the communication suite allows for two-way communication between the user and the information management modules. The information management modules comprise two or more of eleven modules; the eleven modules including
1) a visitor or guest management module;
2) an incident management module;
3) a wellness and telehealth module;
4) a ticketing and event management module;
5) a safety patrolling and emergency alert module;
6) an anonymous reporting module;
7) an attendance management module;
8) a feedback reporting and analysis module;
9) a facility and asset management module;
10) a communication and content management module; and
11) an entitlement and accreditation module.
   Alternatively, the information management modules may comprise at least six of the eleven modules. Alternatively, eight or more modules.

The digital system may be further configured to communicate and interact with the cloud-based system. The data displayed on a display device in the communication suite represents data specifically constructed to demonstrate the functionality of at least one information management module. Alternatively, the data displayed on the display device is provided by the cloud-based system. In this case, the data provided by the cloud-based system may represent real-world data collected during the normal operation of the cloud-based system.

According to another aspect of the present disclosure, an interactive presentation configured for use at a trade show, exhibition, and/or a school or workplace event is provided using the digital system described above and as further defined herein.

According to yet another aspect of the present disclosure, a method for providing an interactive presentation at a trade show, an exhibition, and/or a school or workplace event is provided. This method generally comprises the steps of: providing the digital system as described above and as further defined herein; allowing the user to input and store an instruction into the memory of the platform; the instruction being relative to one or more of the information management modules; allowing the processor to access the memory and perform the instruction that has been input by the user; and communicating data associated with the information management modules according to the instruction to the user via the communication suite in the form of the interactive presentation.

Further areas of applicability will become apparent from the description provided herein. It should be understood that the description and specific examples are intended for purposes of illustration only and are not intended to limit the scope of the present disclosure.

### DESCRIPTION OF THE DRAWINGS

In order that the disclosure may be well understood, there will now be described various forms thereof, given by way of example, reference being made to the accompanying drawings. The components in each of the drawings may not necessarily be drawn to scale, but rather emphasis is placed upon illustrating the principles of the invention.

FIG. 1 is a schematic depiction of a digital system configured to provide an interactive presentation at a trade show, an exhibition, and/or a school or workplace event according to the teachings of the present disclosure.

FIG. 2 is another schematic depiction of a digital system capable of providing a presentation regarding various information management modules simultaneously or consecutively according to the teachings of the present disclosure.

FIG. 3 is a depiction of different information management modules according to the teachings of the present disclosure.

FIG. 4 is a schematic depiction of several information management modules that may be incorporated into the interactive presentation provided by the digital system.

FIG. 5 is a flow diagram that describes the workflow associated with one aspect of the visitor or guest management module.

FIG. 6 is a schematic depiction of additional information management modules that may be incorporated into the interactive presentation provided by the digital system.

FIG. 7, is a flow diagram that describes the workflow for an emergency alert button available in one of the information management modules.

FIG. 8 is a flowchart describing a method for providing an interactive presentation at a trade show, an exhibition, and/or a school or workplace event using the digital system of FIG. 1.

The drawings described herein are for illustration purposes only and are not intended to limit the scope of the present disclosure in any way. It should be understood that throughout the description and drawings, corresponding reference numerals indicate like or corresponding parts and features.

### DETAILED DESCRIPTION

The following description is merely exemplary in nature and is in no way intended to limit the present disclosure or its application or uses. For example, the digital system as formed and used according to the teachings contained herein is described throughout the present disclosure in conjunction with an interactive presentation system for use at a trade show, exposition, or a school or workplace event in order to more fully illustrate the elements and the use thereof. The incorporation and use of such a digital system in other environments or facilities that has a need to manage school or workplace safety, health, and well-being is contemplated to be within the scope of the present disclosure.

For the purpose of this disclosure, the terms “about” and “substantially” are used herein with respect to measurable values and ranges due to expected variations known to those skilled in the art (e.g., limitations and variability in measurements).

For the purpose of this disclosure, the terms “at least one” and “one or more of” an element are used interchangeably and may have the same meaning. These terms, which refer to the inclusion of a single element or a plurality of the elements, may also be represented by the suffix “(s)” at the end of the element. For example, “at least one module”, “one or more modules”, and “module(s)” may be used interchangeably and are intended to have the same meaning.

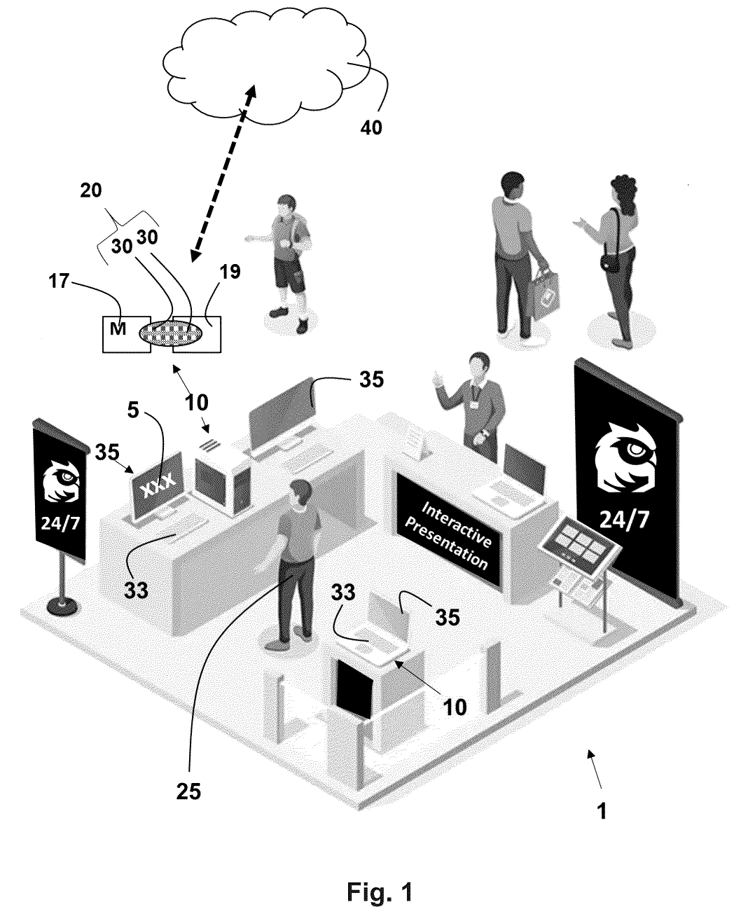

The present disclosure generally provides an improved interactive presentation system and method of using said system that avoids the disadvantages of prior systems and methods while affording additional structural and operating advantages. Referring to FIG. 1, the digital interactive presentation system 5 for a trade show 1, exposition, or a school or workplace event generally comprises: a platform 10 having memory 17 and at least one processor 19; a flexible software architecture 20 configured to interact with a user 25, a plurality of information management modules 30, a communication suite 35; and a user interface 33. The memory 17 of the platform 10 stores instructions received directly from the user 25 and data relative to the information modules 30; the stored data being provided to the user 25 through the communication suite 35 upon the at least one processor 19 executing the stored instructions. The digital interactive presentation system 5 simulates the operation of a cloud-based system 40 configured to manage school or workplace safety, health, and well-being. Thus, the trade show 1, exhibition, and/or school or workplace event, as well as the interactive presentation 5 is relative to safety, health, and well-being, thereby, providing the interactive presentation.

For the purpose of the present disclosure the term “simulates” corresponds to the presentation system mimicking, mirroring, or providing performance that resembles or corresponds to the actual operation of the cloud-based system used to manage school or workplace safety, health, and well-being. A beneficial feature of the digital presentation system is that it describes the many different offerings available in a cloud-based system, e.g., Kokomo 24/7®, focused at safety, health, and well-being management associated with schools and workplaces.

This cloud-based system, generally, comprises the coupling of multiple information management modules relative to safety, health, and well-being, such as the system provided as Kokomo 24/7®. The information management modules in this cloud-based system may include, without limitation, Kokomo Cases™ for incident and compliance management, Kokomo Escalate™ for anonymous reporting and secure data collection & management, Kokomo Notify™ for a scalable communication suite, Kokomo Credentials™ for entitlements and accreditation management, Kokomo Host™ for visitor, workforce, and asset management, Kokomo Forms™ for secure customized surveys, Kokomo Triage™ for emergency management, Kokomo Owlpass™ for fan engagement, ticketing and event management, Kokomo Access™ for asset and resource management, Kokomo Wellness™ for health and wellness management, Kokomo Dashboard™ for predictive analysis and all-in-one analytics, and Kokomo Telehealth™ as a telemedicine or virtual care platform.

The cloud-based system provides a centralized repository, i.e., one source, for all data. This platform provides data coherence and transparency, while meeting compliance requirements. The cloud-based system is modular by nature, which allows for future growth. The key benefits associated with the cloud-based system include improving people safety and workplace safety, creating a culture of inclusivity, safety, and employee engagement, saving employee time and resources through customized workflows, and addressing compliance regulations.

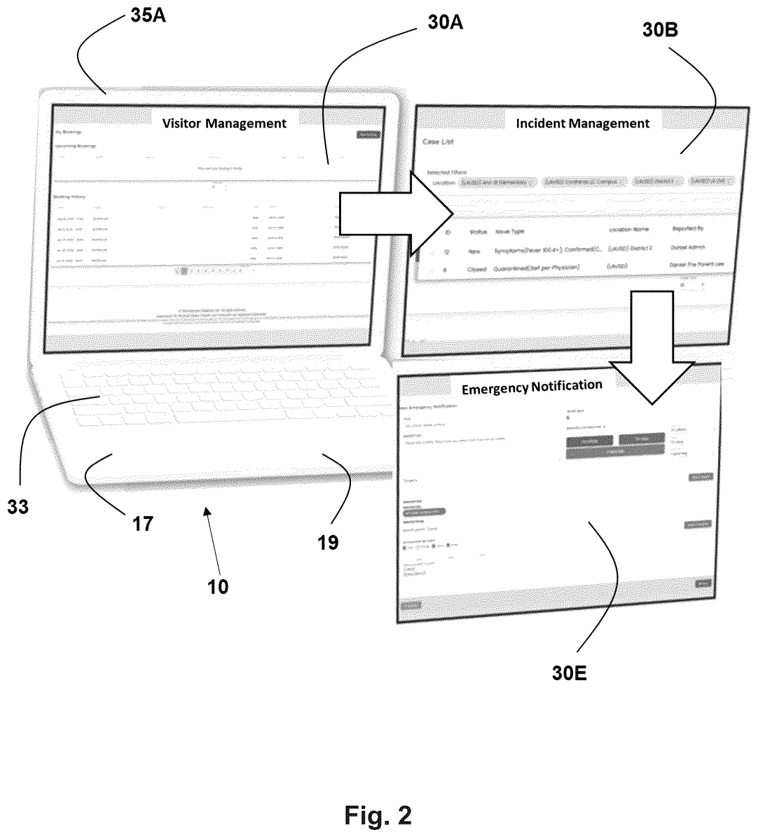

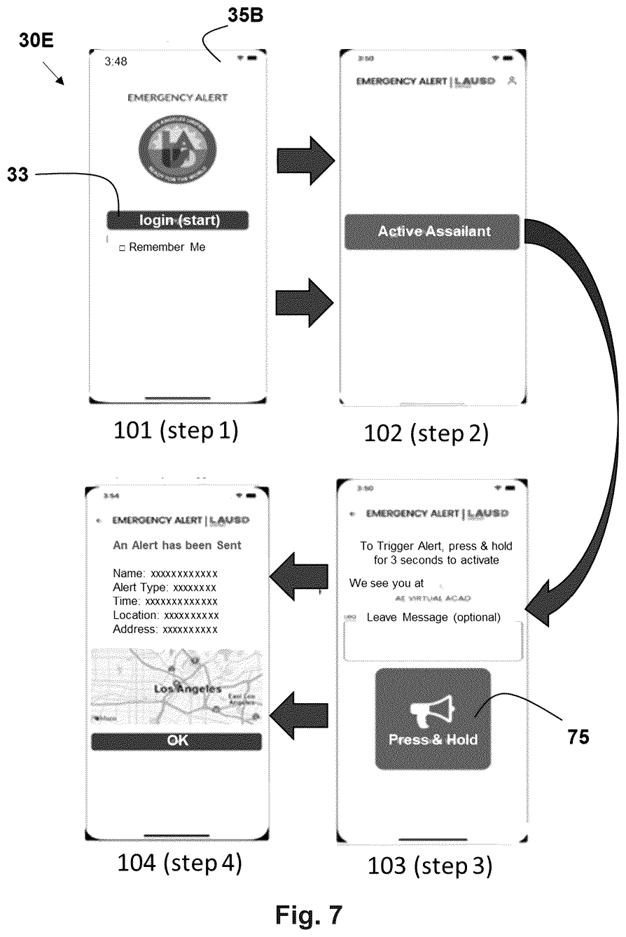

Still referring to FIG. 1, the communications suite 35 may comprise at least one display device 35A (see FIG. 2) configured for use in a building or a confined space and/or at least one mobile device 35B (see FIG. 7). The at least one display device may comprise a television screen or a computer screen or monitor. The at least one mobile device may comprise a cell phone, a personal digital assistant (PDA), or a tablet personal computer. The display device and/or mobile device may also be used to display the user interface. The communication suite 35 may include a variety of different display devices or mobile devices, which can be used in a classroom or a workplace, including robots, kiosks, or a variety of digital signage options including learning-centric touchscreens.

The platform 10 and the communication suite 35 allows for two-way communication between the user 25 and the information management modules 30, as well as to communicate and interact with the cloud-based system 40. The data displayed on the display device 35A in the communication suite 35 may be provided by the cloud-based system 40. The data displayed on the display device 35A in the communication suite 35 may also represent data that has been specifically constructed to demonstrate the functionality of at least one information management module 30 relative to safety, health, and well-being used in the cloud-based system 40. Alternatively, the data provided by the cloud-based system 40 represents real-world data collected during the normal operation of the cloud-based system 40.

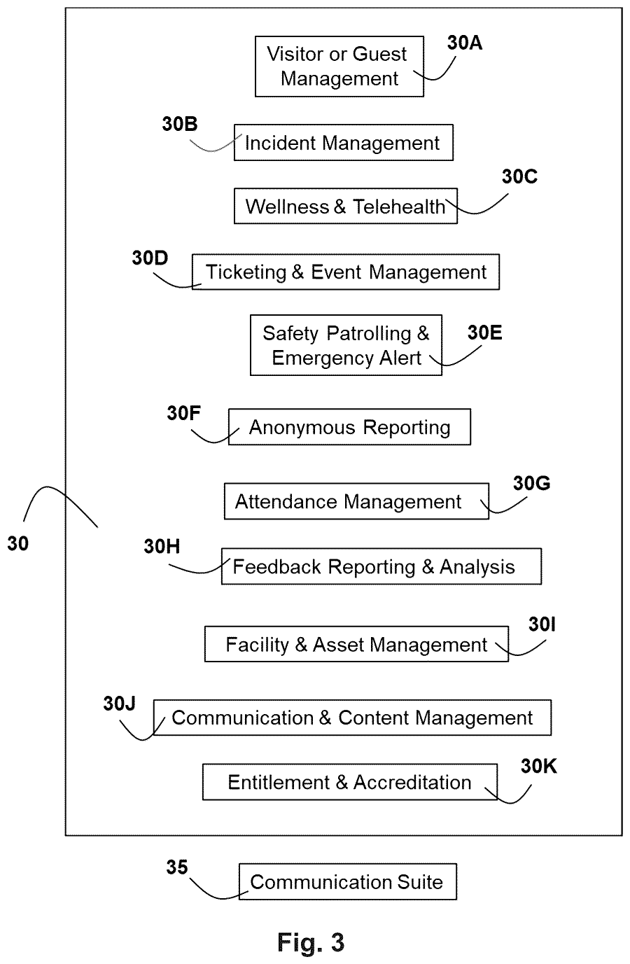

Referring now to FIG. 2, the display device 35A in the communication suite is capable of displaying data obtained from multiple information management modules 30A, 30B, 30E, etc. either sequentially or simultaneously upon the processor 19 acting on a response input into memory 17 of the platform 10 by the user through the user interface 33. As shown in FIG. 3 the different types of information management modules 30 may include, but not be limited to, 1) a visitor or guest management module 30A; 2) an incident management module 30B; 3) a wellness and telehealth module 30C; 4) a ticketing and event management module 30D; 5) a safety patrolling and emergency alert module 30E; 6) an anonymous reporting module 30F; 7) an attendance management module 30G; 8) a feedback reporting and analysis module 30H; 9) a facility and asset management module 30I; 10) a communication and content management module 30J; and 11) an entitlement and accreditation module 30K.

Generally, the interactive digital system 5 includes communication and interaction with at least two of the eleven modules described above and as further defined herein. Alternatively, the digital system 5 interacts and communicates with at least 6 of the eleven modules. Alternatively, the digital system 5 interacts with all eleven of the modules. The architecture of the software associated with the digital system 5 is flexible, such that it is configured to be able to communicate and interact with additional information management modules as required or desired.

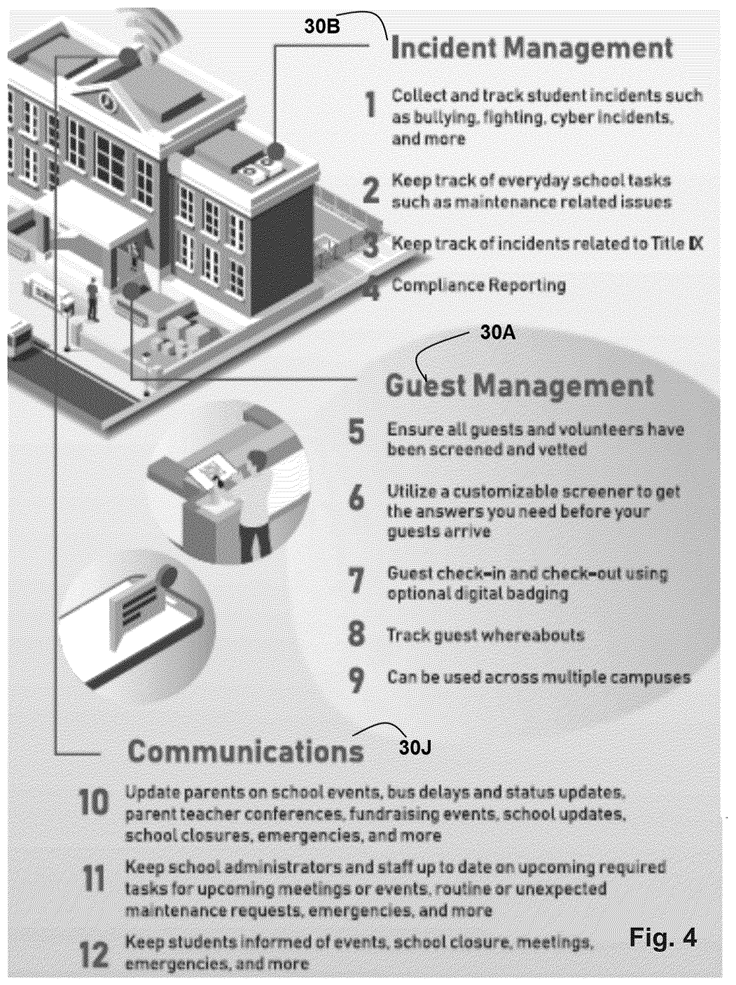

Referring now to FIG. 4, the incident management module 30B provides for incident management in a school environment (e.g., grades K through 12) or in an office, factory, or other workplace. This module describes how to collect and track student incidents such as bullying, fighting, cyber incidents, and more. It describes how to keep track of everyday school tasks such as maintenance related issues, Title IX incidents, and compliance reporting. The incident management module provides a centralized dashboard to help collect, track, manage and respond to both predictable and unpredictable situations.

The incident management module 30B collects, tracks, and manages all types of incidents with one centralized dashboard capable of viewing all locations. This module provides robust analytics that allows for the tracking the workflow of assigned tasks, including necessary student or employee task follow-up, as well as any concerns relative to OSHA compliance regulations. This module 30B provides a safer environment and fosters trust by effectively tracking and rapidly responding to events that affect the school district, workplace, or local community. This incident management module gives organizations streamlined control over the entire incident case process, from reporting and monitoring to responding and recovering. In other words, this module provides a secure system that creates incident reports with ease for analysis, documentation, and compliance along with the ability to access a breakdown of cases by type, roles, location, etc. and/or assign and track follow-up activity with automated tasks. The incident management module includes a highly configurable dashboard, instant notifications, situational awareness, task management, predictive analysis using artificial intelligence (AI) software, regulatory compliance monitoring, and integration with other management modules.

The incident management module 30B is beneficial to the user by being better prepared to track, manage, and respond to predictable and unpredictable events; creating a safe and trusting environment by staying on top of current issues, greatly reducing issue resolution time through centralized reporting; and helping ensure compliance through robust back-end reporting. This module empowers users to report incidents and concerns so that one can quickly initiate appropriate incident management.

Conflict and safety are ongoing concerns for every school, workplace, and community. The ability to prevent, respond and recover increases with early awareness. An increase in reporting by empowering employees with the ability to report incidents publicly or anonymously (24/7), along with automatic escalation of vital reports to specific members through the use of AI filtering and simplifying compliance with robust reporting through use of this module 30B provides the necessary early awareness. Several additional features that may be implement when desired include multi-language reporting, ability to capture the data; and to filter out any illegitimate claims.

Still referring to FIG. 4, the visitor or guest management module 30A ensures that all guests are properly managed through screening and tracking. This module 30A also ensures that all guests and volunteers have been screened and vetted. This module 30A describes how to utilize a customizable screener to get answers needed before guests arrive, as well as how to do guest check-in and check-out using digital badging. It even describes how to track guests across multiple sites and/or campuses including tracking their entry throughout the facilities. Thus, this module 30A ensures that all visitors are properly managed and tracked through screening tools, attendance tracking, and the option for digital badging.

The visitor or guest management module 30A is beneficial to the user by safely managing and screening all visitors or volunteers with customizable surveys that fit the school's or workplace's screening criteria; issuing visitor digital badging based on the survey responses; and monitoring visitors through a centralized dashboard that includes all guest contact information and real-time where about status, even across multiple locations or sites. This module 30A allows visitors to be screened with background checks and for any known or existing safety alerts. This module 30A also provides for the notification of staff regarding both visitor check-ins and check-outs, thereby, gaining certainty of who is in the building.

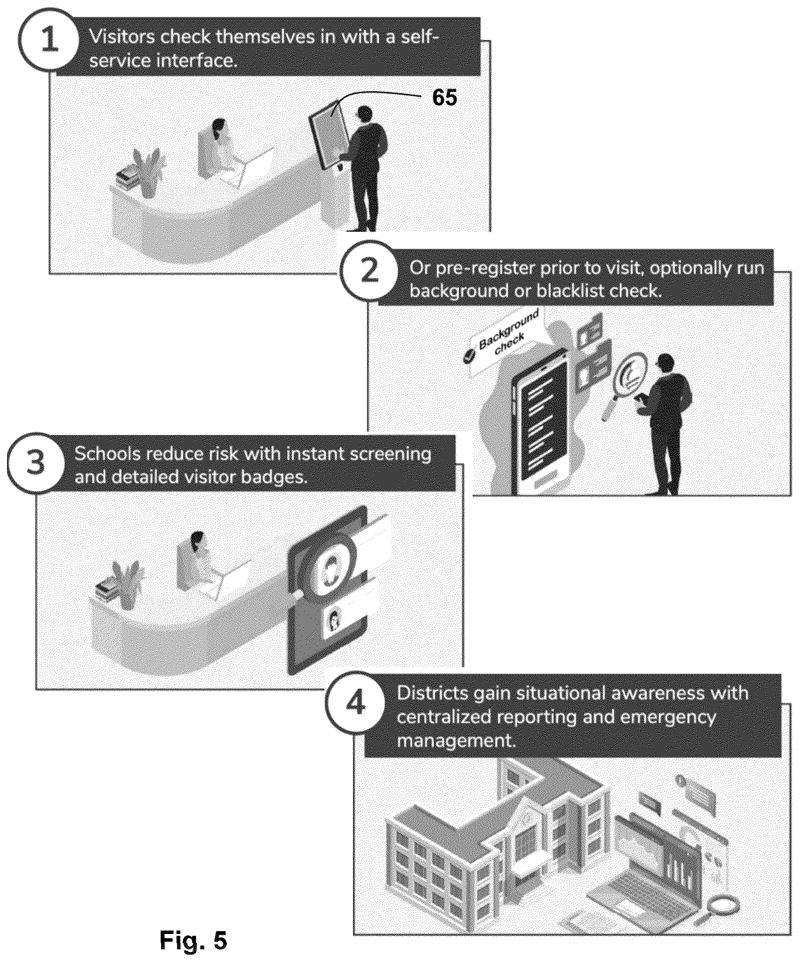

This module 30A can streamline how visitors register and check-in at the front desk. Referring now to FIG. 5, this module 30A allows visitors to check in personally through the use of a self-service interface or pre-register prior to the visit. Pairing a robust visitor management platform with Kiosks 65 as part of the communication suite creates a streamlined experience for visitors. The module allows for the optional running of a background check or if the visitor is listed on any restricted list, e.g., blacklist. Thus, this module 30A provides for building safety and ensures situational awareness without interrupting daily operations or complicating special events. Schools and workplaces reduce their overall risk with instant screening and in providing detailed visitor badges. School districts and/or workplaces gain situational awareness with such centralized reporting and emergency management.

Referring once again to FIG. 4, the communication & content management module 30J helps employers, school administers and parents to stay informed of important updates, exactly when they need it. As for communication features, this module 30J describes, without limitation, how to update parents on school events, bus delays and status, parent/teacher conferences, fundraising events, school closures, and emergencies. The presentation describes how to keep employers and school administrators and staff up to date on upcoming required tasks for meetings, events, routine and unexpected maintenance requests, and emergencies. Likewise, this module 30J describes how to keep students and employees informed of events, school/facility closures, meetings, emergencies, and more. The sending of mass alerts to communities that are large or small can be accomplished in moments for both emergency and non-emergency situations, thereby assisting students, staff, employees, and parents to stay informed of important emergency and non-emergency updates.

With everyone's attention being at a premium today, it's critical to streamline how content can be delivered to the people that need to know or be influenced by the information. In this sense, the communication and content management module can track real-time engagement data and drive in-the-moment adaptations. In other words, this module 30J can make the most of digital signage by managing content more effectively. This module can easily communicate across the school or workplace no matter what device the students, staff, or employees use—including a versatile smart board that helps modern businesses and school districts stay connected.

The communication and content management module 30J is beneficial to the user by keeping teachers, students, employees, and parents informed of important updates during different points of an event, especially in case of emergency; sending notifications via email, text message, mobile push notification, or using voice-to-text; and in saving critical time by using pre-configured alerts to send out during emergencies.

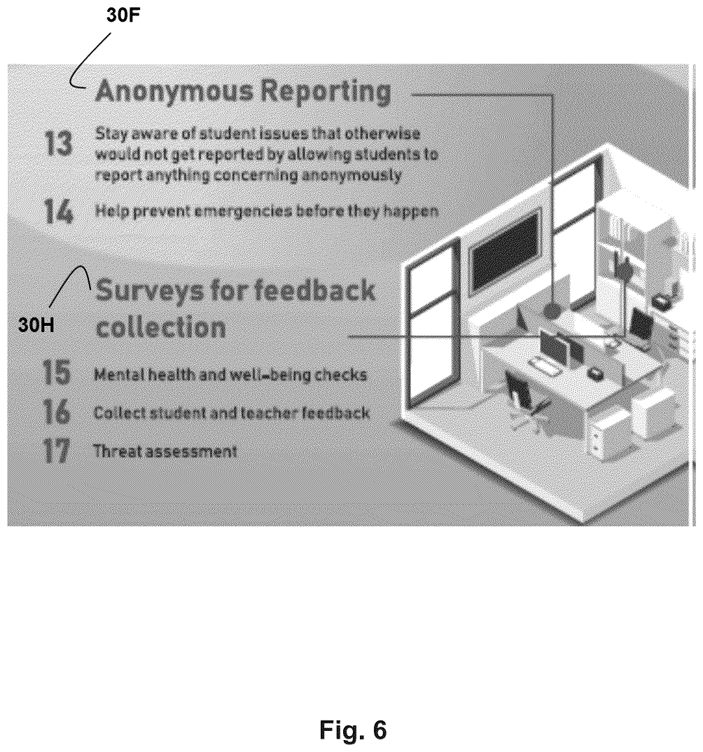

Referring now to FIG. 6, the anonymous reporting module 30F is described to keep authorities aware of issues that might not otherwise be reported, allowing students and/or employees to report anything concerning anonymously. This helps prevent many emergencies before they happen. Anonymous reporting provides students, staff, employees, and community members with a safe and private way to submit concerning behavior without fear of retaliation.

The anonymous reporting module 30F is beneficial to the user by increasing the number of incident reports via the ability to anonymously report incidents 24/7. This results in an increase in the safety of the entire community by collecting information from otherwise unknown incident reports. This module 30F may also utilize artificial intelligence AI filtering in order to enable automatic escalation of important reported incidents.

Still referring to FIG. 6, the feedback reporting and analysis module 30H describes how to prepare and implement surveys to gather feedback from students, teachers, and/or other members of the workforce or staff. This feedback collection includes information related to mental health and well-being checks, student and teacher feedback, and the assessment of any threats. Simple, customizable surveys are used to securely collect the necessary information.

Educational research has found that early screening and early intervention can have a dramatic impact on improving outcomes for young children and students. Schools can acknowledge the root causes of negative behavior or apathy in an active way, identifying students who need support from their school community for any type of social-emotional issue. This module 30H provides access to a set of secure surveys focused on social-emotional learning and mental well-being, including threat assessments and other evaluation tools. No matter what the area of concern may be, the surveys may be customized to fit the required or desired need. This module 30H also provides robust analytics that provide for the collection and analysis of employee, student or school staff responses regarding, without limitation, engagement, productivity, DEI, mental health and wellbeing, and on-boarding/off-boarding. The collected data is understood with the use of visualization and analytical software.

The feedback reporting and analysis module 30H is beneficial to the user by obtaining the student/employee feedback needed to make informed decisions; customizing questions for any specific topic; gaining insight into student/employee feedback via a centralized dashboard, including reports; and performing a threat assessment when necessary.

Due to the rise in chronic absenteeism post-pandemic, the need to ensure that kids are arriving at school on time has never been more important. If students miss school they miss out on meals, learning, and social time, and may become a risk at dropping out of school and/or developing negative behavior. Resources like the attendance (& tardy) management module 30G (see FIG. 3) can help schools track absenteeism and practice early intervention to prevent students from falling into disruptive patterns. This module 30G can securely track students' safe passage onto and off of school buses.

The safety patrolling & emergency alert module 30E (see FIG. 3) allows schools to quickly and easily track assets and people, as well as view real-time data with robust dashboards and predictive analytics. This module provides operational effectiveness that can close the gap and empower students and/or the workforce. This module 30E helps ensure the safety of all students/employees and the entire school or workplace community by providing an Emergency Alert button for incidents requiring immediate attention or police intervention. This module 30E assists in ensuring the safety of all students, employees, and/or community members with a way to call for help during times of extreme emergency. This module can also track and manage student/employee patrols or inspections of sites and facilities.

The safety patrolling & emergency alert module 30E is beneficial to the user by providing an optional Emergency Alert button that allows students to report cases of extreme emergency; increasing emergency readiness and reducing response time; ensuring students are safe using ‘A-Ok’ button; enabling two-way communication for those in need and when desired or necessary contacting local police/fire or other emergency personnel.

Referring now to FIG. 7, an emergency alert button 75 located in the safety patrolling & emergency alert module 30E can be accessed via an user interface 33 shown on any classroom unit, wall unit, AND, kiosk, or mobile device 35B. This function provides the student/employee with the ability to activate and send an alert to emergency personnel with GPS tracking of the communication device being enabled. The emergency personnel may include, without limitation, medical personnel, school administration, and/or law enforcement. Alternatively, the emergency alert button 75 may be accessed by a unit that is wearable, such as a necklace, bracelet/watch, or clipped to a belt. The workflow associated with the emergency alert button 75 located in the safety patrolling & emergency alert module 30E used with a mobile device 35B generally comprises the steps of: 1) login or starting 101 the module; 2) automatic activation of the panic button 102 if an active assailant is encountered; or 3) provide additional (optional) message for other emergency situations and/or activate an alert 103; and 4) optionally view 104 details of the alert that has been sent. A wearable device may also contain a button that once pushed by the a student or employee may automatically activate the emergency alert button 75 directing local emergency, school, and/or law enforcement personnel to the indicated global positioning system (GPS) location.

In an effort to improve access to physical and mental well-being medical services, advance health equity for underserved populations, and address a nation-wide shortage of school/workplace resources, the wellness and telehealth module 30C (see FIG. 3) provides schools and employers with telehealth services to serve their community members. This module 30C increases the number of students/employees who can receive high-quality care from a leading team of remote medical providers, improving outcomes and decrease time away from the classroom or workplace. This module 30C manages student/employee health and well-being with telehealth and records management, in compliance with HIPAA requirements

The wellness and telehealth module 30C is configured to allow communication between the student/employee and a medical professional either via a telephone, an internet connection, or the like. This module 30C securely manages employee health and well-being including mental health screenings and records management, such as vaccination records, while maintaining compliance with HIPPA requirements. The telehealth service gives students/employees access to on-demand virtual care by providing the students/employees with resources focused at keeping the students or employees in the classroom or workplace, thereby, reducing absenteeism.

By using a comprehensive telehealth platform, students, employees and community members can get the care they need, whenever and wherever they need it. When a digital telehealth platform is paired with video call hardware from a leading manufacturer, the school or employer provides an innovative virtual healthcare solution that can transform the way organizations deliver benefits to their members.

The facility and asset management module 30I (see FIG. 3) provides for the management of school/workplace spaces like desks, rooms, or large gathering areas, along with easily tracking reservations or requests. This module 30I can also provide technology device licenses, as well as issue service or repair tickets. When desirable, this module 30I may also be used to assess educators in the classroom or seminars by providing easily tracked observations in one integrated database. This module may also be used to manage shared school or company technology devices, such as laptops, easily tracking occupancy, service and repair tickets.

The ticketing and event management module 30D provides one comprehensive tool to help streamline events through improved attendee and venue management. This module 30D allows schools and organizations to send personalized emails, texts, and voice messages before, during, or after an event or emergency. Thus, everyone can be kept informed and up to date regarding the event. It is well established that fast and effective notifications can save lives in emergency situations. This module 30D can deploy one-click notifications to all users, a subset of users, or users fulfilling a specific check-in status. In this manner, the module 30D can quickly find out who is safe and who needs attention during an event with the implementation of an “A-OK” feature. In this manner, respondents are able to mark themselves as safe or in need of assistance during an emergency with track GPS location enabled.

The ticketing and event management module 30D may be beneficial to the user by providing instant notifications, two-way communication, emergency alerts, situational analysis, and geo-fencing. This module 30D captures critical data like persons involved, geolocation, videos, pictures, voice recordings, tags, forms, and the occurrence of any changes to the event.

The entitlement & accreditation module 30K provides a safe place to store accreditation, such as certifications, professional development, vaccinations, or diagnostic results. This module 30K not only streamlines the secure management of critical certifications, it is configured to collect, store, track, and manage records for all members of the school, workplace, and/or community. This module 30K may provide automated recertification deadline reminders and failed response alerts using personal emails or a centralized dashboard. When desirable, this module 30K may also provide artificial intelligence AI auto verification to verify submissions for re-certifications.

According to another aspect of the present disclosure, an interactive presentation is provided for use at a trade show, exhibition, and/or a school or workplace event. This interactive presentation is provided using the digital system as described above and as further defined herein. In this respect, one or more of the embodiments of the digital system may be utilized alone or in combination to provide the interactive presentation to the user.

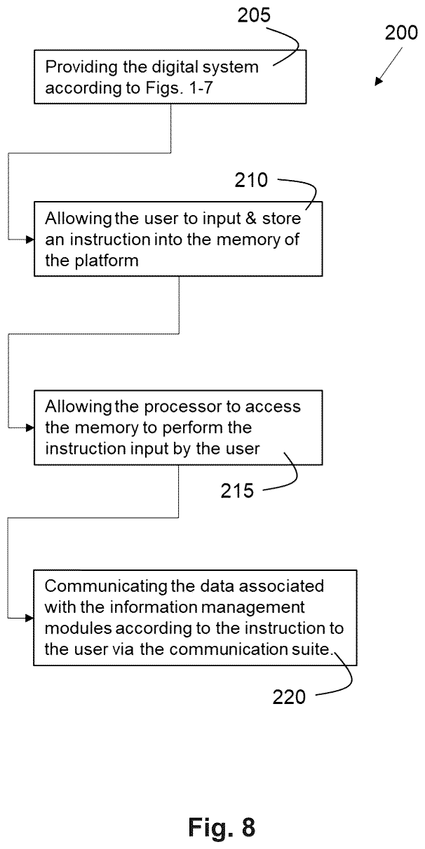

According to yet another aspect of the present disclosure, a method for providing an interactive trade show presentation for safety, health, and well-being at a trade show, an exhibition, and/or a school or workplace event, is substantially shown and described herein. Referring now to FIG. 8, the method 200 generally comprises the steps of: providing 205 the digital system as described above and as further defined herein; allowing 210 the user to input and store an instruction into the memory of the platform; the instruction being relative to one or more of the information management modules; allowing 215 the processor to access the memory and perform the instruction that has been input by the user; and communicating 220 data associated with the information management modules according to the instruction to the user via the communication suite in the form of the interactive presentation.

Within this specification, embodiments have been described in a way which enables a clear and concise specification to be written, but it is intended and should be appreciated that embodiments may be variously combined or separated without parting from the invention. For example, it will be appreciated that all preferred features described herein are applicable to all aspects of the invention described herein.

Those skilled-in-the-art, in light of the present disclosure, will appreciate that many changes can be made in the specific embodiments which are disclosed herein and still obtain alike or similar result without departing from or exceeding the spirit or scope of the disclosure. One skilled in the art will further understand that any properties reported herein represent properties that are routinely measured and can be obtained by multiple different methods. The methods described herein represent one such method and other methods may be utilized without exceeding the scope of the present disclosure.

The foregoing description of various forms of the invention has been presented for purposes of illustration and description. It is not intended to be exhaustive or to limit the invention to the precise forms disclosed. Numerous modifications or variations are possible in light of the above teachings. The forms discussed were chosen and described to provide the best illustration of the principles of the invention and its practical application to thereby enable one of ordinary skill in the art to utilize the invention in various forms and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A digital system for providing an interactive presentation at a trade show, an exhibition, or a school or workplace event, the digital system comprising:
a platform having memory and at least one processor;
a flexible software architecture configured to interact with a user, a plurality of information management modules, and a communication suite; and
a user interface;
wherein the memory of the platform stores instructions received directly from the user and data relative to the information modules; the stored data being provided to the user through the communication suite upon the at least one processor executing the stored instructions;
wherein the digital system simulates the function or operation of a cloud-based system configured to manage school or workplace safety, health, and well-being, thereby, providing the interactive presentation.

2. The digital system according to claim 1, wherein the communication suite comprises at least one display device configured for use in a building or a confined space and/or at least one mobile device.

3. The digital system according to claim 2, wherein the at least one display device comprises a television screen or a computer screen or monitor; and/or the at least one mobile device comprises a cell phone, a personal digital assistant (PDA), or a tablet personal computer.

4. The digital system according to claim 1, wherein the trade show, the exhibition, and/or the school or workplace event is relative to safety, health, and well-being.

5. The digital system according to claim 1, wherein the platform and the communication suite allows for two-way communication between the user and the information management modules.

6. The digital system according to claim 1, wherein the information management modules comprise two or more of eleven modules; the eleven modules including:
1) a visitor or guest management module;
2) an incident management module;
3) a wellness and telehealth module;
4) a ticketing and event management module;
5) a safety patrolling and emergency alert module;
6) an anonymous reporting module;
7) an attendance management module;
8) a feedback reporting and analysis module;
9) a facility and asset management module;
10) a communication and content management module; and
11) an entitlement and accreditation module.

7. The digital system according to claim 6, wherein the information management modules comprise at least six of the eleven modules.

8. The digital system according to claim 1, wherein the digital system is further configured to communicate and interact with the cloud-based system.

9. The digital system according to claim 8, wherein the data displayed on a display device in the communication suite is provided by the cloud-based system.

10. The digital system according to claim 1, wherein the data displayed on a display device in the communication suite represents data specifically constructed to demonstrate the functionality of at least one information management module.

11. The digital system according to claim 9, wherein the data provided by the cloud-based system represents real-world data collected during the normal operation of the cloud-based system.

12. An interactive presentation configured for use at a trade show, exhibition, and/or a school or workplace event; the interactive presentation being provided using the digital system according to claim 6.

13. The interactive presentation according to claim 12, wherein the data displayed on the display device represents data specifically constructed to demonstrate the functionality of a plurality of information management modules.

14. The interactive presentation according to claim 13, wherein the data displayed on the display device is provided by a cloud-based system.

15. The interactive presentation according to claim 12, wherein the data displayed on the display device is provided by a cloud-based system;
wherein the data provided by the cloud-based system represents real-world data collected during the normal operation of the cloud-based system relative to school or work place safety, health, and well-being.

16. A method for providing an interactive presentation at a trade show, an exhibition, and/or a school or workplace event, the method comprising the steps of:
providing the digital system according to claim 1;
allowing the user to input and store an instruction into the memory of the platform;
the instruction being relative to one or more of the information management modules;
allowing the processor to access the memory and perform the instruction that has been input by the user; and
communicating data associated with the information management modules according to the instruction to the user via the communication suite in the form of the interactive presentation.

17. The method according to claim 16, wherein the data displayed on a display device in the communication suite represents data specifically constructed to demonstrate the functionality of a plurality of the information management modules.

18. The method according to claim 17, wherein the data displayed on the display device is provided by a cloud-based system.

19. The method according to claim 16, wherein the data displayed on a display device om the communication suite is provided by a cloud-based system;
wherein the data provided by the cloud-based system represents real-world data collected during the normal operation of the cloud-based system relative to school or work place safety, health, and well-being.

20. The method according to claim 16, wherein the information management modules comprise two or more of eleven modules; the eleven modules including:
1) a visitor or guest management module;
2) an incident management module;
3) a wellness and telehealth module;
4) a ticketing and event management module;
5) a safety patrolling and emergency alert module;
6) an anonymous reporting module;
7) an attendance management module;
8) a feedback reporting and analysis module;
9) a facility and asset management module;
10) a communication and content management module; and
11) an entitlement and accreditation module.
